(19) United States
(12) Patent Application Publication
(10) Pub. No.: US 2012/0138903 A1
(43) Pub. Date: Jun. 7, 2012

(54) Graphene Substrates And Methods Of Fabricating The Same

(75) Inventors: Hyun-jong Chung, Hwaseong-si (KR); Sun-ae Seo, Hwaseong-si (KR); Sung-hoon Lee, Hwaseong-si (KR); Jin-seong Heo, Suwon-si (KR); Hee-jun Yang, Seoul (KR)

(73) Assignee: SAMSUNG ELECTRONICS CO., LTD., Suwon-si (KR)

(21) Appl. No.: 13/308,749

(22) Filed: Dec. 1, 2011

(30) Foreign Application Priority Data
Dec. 1, 2010 (KR) 10-2010-0121331

(51) Int. Cl. H01L 29/12; H01L 21/20; B82Y 99/00; B82Y 40/00

(52) U.S. Cl. 257/29; 438/478; 257/E29.068; 257/E21.09; 977/734

(57) ABSTRACT

The graphene substrate may include a metal oxide film on a substrate, and a graphene layer on the metal oxide film. The concentration of oxygen in the metal oxide film may be gradually reduced from the substrate towards the graphene layer, and the graphene layer may be formed directly on the metal oxide film.

### CROSS-REFERENCE TO RELATED APPLICATIONS

This application claims the benefit of Korean Patent Application No. 10-2010-0121331, filed on Dec. 1, 2010, in the Korean Intellectual Property Office, the entire contents of which is incorporated herein by reference.

### BACKGROUND

1. Field

Example embodiments relate to graphene substrates having a graphene layer grown directly on an oxide film and methods of fabricating the graphene substrates.

2. Description of the Related Art

Graphene having a 2-dimensional hexagonal carbon structure is a new material that can replace semiconductors. Also, graphene is a zero gap semiconductor and has a carrier mobility of 100,000 cm²V⁻¹s⁻¹ at room temperature, which is approximately 100 times faster than that of conventional silicon. Therefore, graphene may be applied to a device that operates at high speed, for example, a radio frequency (RF) device.

When graphene is formed in a graphene nano-ribbon (GNR) having a channel width of less than 10 nm, a band gap may be formed due to a size effect. A field effect transistor can be manufactured using such a GNR. A graphene electronic device, e.g., a field effect transistor or an RF transistor, may be an electronic device that includes graphene.

In an graphene electronic device, in order to form graphene on a substrate, after forming graphene on a typical metal and removing the typical metal, the graphene may be transferred to a substrate on which an insulating layer is formed. A defect may occur in the graphene in the transfer process of the graphene.

### SUMMARY

Example embodiments provide graphene substrates in which graphene is grown directly on an insulating film without transferring the graphene and a method of fabricating the graphene substrates. Additional aspects will be set forth in part in the description which follows and, in part, will be apparent from the description, or may be learned by the practice of example embodiments.

According to example embodiments, a graphene substrate may include a substrate, a metal oxide film on the substrate, and a graphene layer on the metal oxide film, wherein the concentration of oxygen in the metal oxide film may be gradually reduced from the substrate towards the graphene layer.

The metal oxide film may be formed of an oxide selected from the group consisting of nickel oxide (NiO), cupper oxide (CuO), and platinum oxide (PtO). The metal oxide film may have a thickness in a range from about 100 nm to about 300 nm. The graphene layer may include a single layer of graphene or bi-layers of graphene. The graphene substrate may further include a buffer layer between the substrate and the metal oxide film. The substrate may be a conductive silicon substrate.

According to example embodiments, a method of fabricating a graphene substrate may include depositing a metal oxide film on a substrate, and depositing a graphene layer on the metal oxide film.

The concentration of oxygen in the metal oxide film may be gradually reduced from the substrate towards the graphene layer. The depositing the metal oxide film may include gradually reducing a supply concentration of oxygen into a chamber while sputtering a metal of the metal oxide film on the substrate.

The depositing the metal oxide film may include forming a metal film having a thickness in a range from about 5 nm to about 10 nm on a surface of the metal oxide film. The depositing the graphene layer may include converting the metal film that contacts the graphene layer to a non-conductive film by diffusing a metal of the metal film into the metal oxide film by annealing the metal film.

### BRIEF DESCRIPTION OF THE DRAWINGS

These and/or other aspects will become apparent and more readily appreciated from the following description of example embodiments, taken in conjunction with the accompanying drawings of which:

FIG. 1 is a schematic cross-sectional view of the structure of a graphene substrate according to example embodiments;

FIGS. 2A and 2B are cross-sectional views showing a method of fabricating a graphene substrate according to example embodiments; and

FIGS. 3A through 3C are cross-sectional views showing a method of fabricating a graphene substrate according to example embodiments.

### DETAILED DESCRIPTION

Reference will now be made in detail to embodiments, examples of which are illustrated in the accompanying drawings. In the drawings, lengths and sizes of layers and regions may be exaggerated for clarity and like reference numerals refer to the like elements throughout.

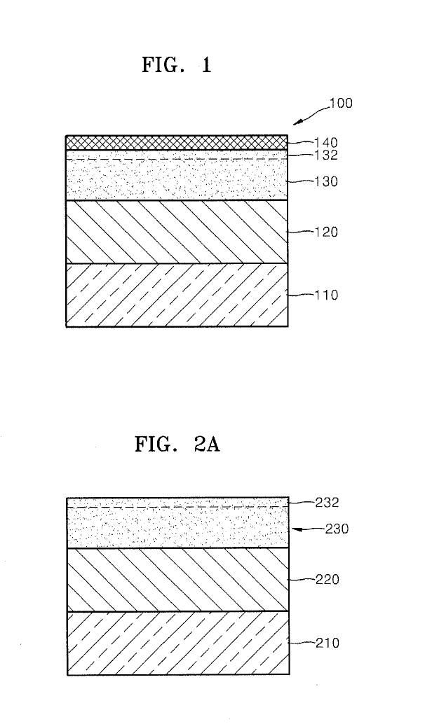

FIG. 1 is a schematic cross-sectional view of the structure of a graphene substrate 100 according to example embodiments. Referring to FIG. 1, a buffer layer 120 may be formed on a silicon substrate 110. The buffer layer 120 may be formed of a silicon oxide. The buffer layer 120 facilitates the forming of a metal oxide film above the silicon substrate 110.

A metal oxide film 130 may be formed on the buffer layer 120. The metal oxide film 130 may be formed of nickel oxide (NiO), copper oxide (CuO), or platinum oxide (PtO) to a thickness in a range from about 100 nm to about 300 nm. The metal oxide film 130 may be formed by controlling the concentration of oxygen O₂ while sputtering a metal, for example, Ni by supplying oxygen together with argon Ar as a carrier gas. While the metal oxide film 130 is deposited on the buffer layer 120, the concentration of oxygen may be gradually reduced, and thus, a Ni-rich film 132 may be formed on a surface layer of the NiO film 130. The Ni-rich film 132 may be substantially a non-conductive film. The buffer layer 120 may be omitted.

A graphene layer 140 may be formed on the metal oxide film 130. The graphene layer 140 may be formed by a chemical vapor deposition (CVD) method and may include a single layer of graphene or bi-layers of graphene.

The graphene layer may be directly deposited on the metal oxide film on the substrate according to example embodiments. Therefore, in order to fabricate a graphene electronic device, there may be no need to transfer a graphene layer to another substrate on which an insulating layer is formed by separating the graphene layer. That is, a graphene electronic device may be fabricated without the need of transferring of the graphene layer, thereby preventing or reducing the damage to the graphene.

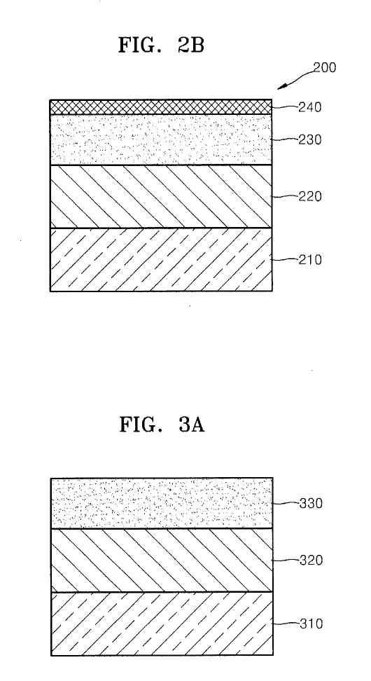

FIGS. 2A and 2B are cross-sectional views showing a method of fabricating a graphene substrate 200 according to example embodiments. Referring to FIG. 2A, a buffer layer 220 may be formed on a substrate 210, for example, a silicon substrate 210. The buffer layer 220 may be formed of silicon oxide or silicon nitride. The buffer layer 220 facilitates forming of a metal oxide film 230, which will be described later, on the silicon substrate 210.

The metal oxide film 230 may be formed on the buffer layer 220. The metal oxide film 230 may be formed of NiO, CuO, or PtO to a thickness in a range from about 100 nm to about 300 nm. The metal oxide film 230, that is, a NiO film 230 may be formed by supplying oxygen O₂ together with argon Ar as a carrier gas while sputtering a metal, for example, Ni. At this point, while the NiO film 230 is deposited on the buffer layer 220, the concentration of oxygen may be gradually reduced by controlling the supplying amount of oxygen. That is, the concentration of oxygen in the NiO film 230 may be gradually reduced with a gap between the NiO film 230 and the buffer layer 220. In order to form a Ni film 232 on a surface of the NiO film 230, the surface of the NiO film 230 may further be hydrogen plasma processed.

Referring to FIG. 2B, a graphene layer 240 may be formed on the NiO film 230 by supplying a carbon-containing gas using a conventional method. The graphene layer 240 may be formed by using a CVD method, and may include a single layer of graphene or bi-layers of graphene. In order to form the graphene layer 240, a carbon-containing gas may be supplied into a chamber (not shown) in which the silicon substrate 210 is disposed. The carbon-containing gas may be CH₄, C₂H₂, C₂H₄, or CO. The deposition of the graphene layer 240 may be performed at a temperature in a range from about 650° C. to about 900° C. In a process of forming the graphene layer 240, the graphene layer 240 may be formed on the Ni film 232, and a thermal annealing of the deposition process allows Ni of the Ni film 232 to diffuse into the surface of the NiO film 230 to make the surface of the NiO film 230 a non-conductive surface. Additional thermal annealing may be performed. In particular, Ni may be readily diffused between columns of the NiO film 230 because the NiO film 230 may be formed on the buffer layer 220 as a column shape.

The Ni film 232 may be used for forming the graphene layer 240 thereon, but nevertheless, disappears by diffusing into the NiO film 230 due to the thermal annealing. Therefore, the Ni film 232 may be an intermediate film.

The graphene layer 240 may be deposited on the surface of the NiO film 230 using a metal, for example, Ni, and the surface of the NiO film 230 may be changed to a non-conductive surface by diffusing Ni into the NiO film 230. Therefore, transferring the graphene layer 240 formed on a surface of the non-conductive film (the NiO film 230) to another substrate on which an additional insulating film is formed is not necessary.

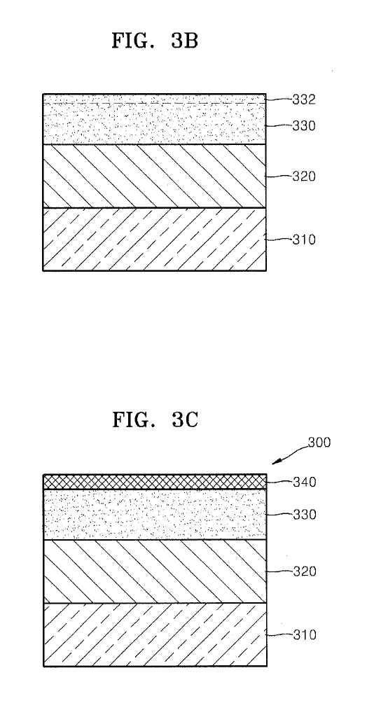

FIGS. 3A through 3C are cross-sectional views showing a method of fabricating a graphene substrate 300 according to example embodiments. Referring to FIG. 3A, a buffer layer 320 may be formed on a substrate, for example, a silicon substrate 310. The buffer layer 320 may be formed of silicon oxide or silicon nitride. The buffer layer 320 facilitates the forming of a metal oxide film 330 on the silicon substrate 310.

The metal oxide film 330 may be formed on the buffer layer 320. The metal oxide film 330 may be formed of NiO, CuO, or PtO to a thickness in a range from about 100 nm to about 300 nm. The metal oxide film 330, that is, a NiO film 330 may be formed by supplying argon Ar as a carrier gas and oxygen O₂ while sputtering a metal, for example, Ni.

When the metal oxide film 330 is formed, a Ni-rich film may be formed on a surface of the metal oxide film 330 by gradually reducing the concentration of oxygen by controlling the supply of oxygen while the metal oxide film 330 is deposited from the surface of the buffer layer 320.

Referring to FIG. 3B, a Ni film 332 may be formed by hydrogen plasma processing the surface of the NiO film 330. The Ni film 332 may be formed to have a thickness in a range from about 5 nm to about 10 nm.

Referring to FIG. 3C, a graphene layer 340 may be formed on the Ni film 332 by supplying a carbon-containing gas by using a conventional method. The graphene layer 340 may be formed by using a CVD method, and may include a single layer of graphene or bi-layers of graphene. In order to form the graphene layer 340, a carbon-containing gas may be supplied into a chamber (not shown) in which the silicon substrate 310 is disposed. The carbon-containing gas may be CH₄, C₂H₂, C₂H₄, or CO. The deposition of the graphene layer 340 may be performed at a temperature in a range from about 650° C. to about 900° C. In a process of forming the graphene layer 340, the graphene layer 340 may be formed by using the Ni film 332, and a thermal annealing of the Ni film 232 at the deposition process allows Ni of the Ni film 332 to diffuse into the surface of the NiO film 330 to make the surface of the NiO film 330 as a non-conductive surface. In particular, Ni may be readily diffused between columns of the NiO film 330 because the NiO film 330 may be formed on the buffer layer 320 in a column shape.

The Ni film 332 may be used for forming the graphene layer 340, but nevertheless, disappears by diffusing into the NiO film 330 due to the thermal annealing. Therefore, the Ni film 332 may be an intermediate film.

The graphene layer 340 may be deposited on the surface of the NiO film 330 using the Ni film 332 and the surface of the NiO film 330 may be changed to a non-conductive surface by diffusing Ni into the NiO film 330. Therefore, transferring the graphene layer 340 formed on a surface of the non-conductive film (the NiO film 330) to another substrate on which an additional insulating film is formed is unnecessary.

In a graphene substrate according to example embodiments, a graphene layer may be directly deposited on a metal oxide film formed on a silicon substrate. Therefore, in order to form a graphene electronic device, transferring a graphene layer on a substrate on which an insulating layer is formed after separating the graphene layer may not be necessary. That is, a graphene electronic device can be fabricated without the need of transferring a graphene layer, and thus, damage of graphene during the transferring of the graphene layer may be prevented or reduced.

In a method of fabricating a graphene substrate according to example embodiments, while forming a graphene layer on a surface of a metal film by using the metal film as an intermediate film, the metal film that contacts the graphene layer may be changed into a non-conductive surface by diffusing a metal of the metal film into a metal oxide film thereunder. Therefore, a graphene electronic device can be directly fabricated using the graphene substrate without the need of transferring the graphene layer to a substrate on which an insulating layer is formed.

It should be understood that the example embodiments described therein should be considered in a descriptive sense only and not for purposes of limitation. Descriptions of features or aspects within each example embodiment should typically be considered as available for other similar features or aspects in other example embodiments.

What is claimed is:

1. A graphene substrate comprising:
a substrate;
a metal oxide film on the substrate; and
a graphene layer on the metal oxide film,
wherein the concentration of oxygen in the metal oxide film is gradually reduced from the substrate towards the graphene layer.

2. The graphene substrate of claim 1, wherein the metal oxide film is formed of a material selected from the group consisting of NiO, CuO, and PtO.

3. The graphene substrate of claim 1, wherein the metal oxide film has a thickness in a range from about 100 nm to about 300 nm.

4. The graphene substrate of claim 1, wherein the graphene layer includes a single layer of graphene or bi-layers of graphene.

5. The graphene substrate of claim 1, further comprising:
a buffer layer between the substrate and the metal oxide film.

6. The graphene substrate of claim 1, wherein the substrate is a conductive substrate.

7. The graphene substrate of claim 6, wherein the substrate is a silicon substrate.

8. A method of fabricating a graphene substrate, the method comprising:
depositing a metal oxide film on a substrate; and
depositing a graphene layer on the metal oxide film.

9. The method of claim 8, wherein the concentration of oxygen in the metal oxide film is gradually reduced from the substrate towards the graphene layer.

10. The method of claim 9, wherein the depositing the metal oxide film includes gradually reducing a supply concentration of oxygen into a chamber while sputtering a metal of the metal oxide film on the substrate.

11. The method of claim 10, wherein the depositing the metal oxide film includes forming a metal film having a thickness in a range from about 5 nm to about 10 nm on a surface of the metal oxide film.

12. The method of claim 11, wherein the depositing the graphene layer includes converting the metal film that contacts the graphene layer to a non-conductive film by diffusing a metal of the metal film into the metal oxide film during an annealing process.

13. The method of claim 10, wherein the depositing the metal oxide film comprises forming a metal film on a surface of the metal oxide film by hydrogen plasma processing the surface of the metal oxide film.

14. The method of claim 13, wherein the metal film has a thickness in a range from about 5 nm to about 10 nm.

15. The method of claim 13, wherein the depositing the graphene layer comprises converting the metal film that contacts the graphene layer to a non-conductive film by diffusing a metal of the metal film into the metal oxide film during an annealing process.

16. The method of claim 8, wherein the depositing the metal oxide film comprises forming a metal film on a surface of the metal oxide film by hydrogen plasma processing the surface of the metal oxide film.

17. The method of claim 16, wherein the metal film has a thickness in a range from about 5 nm to about 10 nm.

18. The method of claim 17, wherein the depositing the graphene layer comprises converting the metal film that contacts the graphene layer to a non-conductive film by diffusing a metal of the metal film into the metal oxide film by annealing the metal film.

19. The method of claim 8, wherein the depositing the metal oxide film comprises forming a metal oxide film selected from the group consisting of NiO, CuO, and PtO.

20. The method of claim 8, wherein the metal oxide film has a thickness in a range from about 100 nm to about 300 nm.

21. The method of claim 8, wherein the graphene layer is a single layer of graphene or bi-layers of graphene.

22. The method of claim 8, further comprising:
forming a buffer layer between the substrate and the metal oxide film.

23. The method of claim 8, wherein the substrate is a conductive substrate.

24. The method of claim 23, wherein the substrate is a silicon substrate.
